(19) United States
(12) Patent Application Publication
(10) Pub. No.: US 2025/0090975 A1
(43) Pub. Date: Mar. 20, 2025

(54) REMOVING IMPURITIES FROM PRECURSORS

(71) Applicant: ENTEGRIS, INC., Billerica, MA (US)

(72) Inventors: Michael Watson, Leander, TX (US); Cristian Ocampo, Austin, TX (US); Joseph E. Reynolds, III, Leander, TX (US); Scott L. Battle, Cedar Park, TX (US); Sara Moghaddam, Dripping Springs, TX (US); Benjamin R. Garrett, Leander, TX (US)

(21) Appl. No.: 18/888,013

(22) Filed: Sep. 17, 2024

Related U.S. Application Data
(60) Provisional application No. 63/539,025, filed on Sep. 18, 2023.

(51) Int. Cl. B01D 7/00; C01F 7/62; C01G 39/00; C01G 39/04; C01G 41/04; C23C 16/44

(52) U.S. Cl. CPC B01D 7/00; C01F 7/62; C01G 39/006; C01G 39/04; C01G 41/04; C23C 16/4402

(57) ABSTRACT

Methods for removing impurities from precursors and related systems are provided. A method comprises at least one thermal cycle. The at least one thermal cycle comprises one or more of the following steps: heating a vessel comprising a precursor and at least one impurity to a temperature for a duration sufficient to vaporize at least a portion of the at least one impurity; measuring a vapor pressure within the vessel to obtain a measured vapor pressure and comparing the measured vapor pressure to a set point vapor pressure; and when the measured vapor pressure is above or within the set point vapor pressure, removing, from the vessel, at least a portion of a vapor comprising the at least one impurity. Other methods and systems are provided herein.

### CROSS-REFERENCE TO RELATED APPLICATIONS

The present application claims priority to and benefit of U.S. Provisional Patent Application No. 63/539,025, filed Sep. 18, 2023 and entitled “REMOVING IMPURITIES FROM PRECURSORS,” the entirety of which is herein incorporated by reference.

### FIELD

The present disclosure relates to removing impurities from precursors and related systems and related methods.

### BACKGROUND

The presence of impurities in precursors used for semiconductor fabrication results in defects and undesired process variability.

### SUMMARY

Some embodiments relate to a method. In some embodiments, the method at least one thermal cycle, wherein the at least one thermal cycle comprises one or more of the following steps: heating a vessel comprising a precursor and at least one impurity to a temperature for a duration sufficient to vaporize at least a portion of the at least one impurity; measuring a vapor pressure within the vessel to obtain a measured vapor pressure and comparing the measured vapor pressure to a set point vapor pressure; and when the measured vapor pressure is above or within the set point vapor pressure, removing, from the vessel, at least a portion of a vapor comprising the at least one impurity. In some embodiments, when the vapor comprising the at least one impurity is removed from the vessel, at least 90% of the at least one impurity is removed from the vessel.

Some embodiments relate to a method. In some embodiments, the method comprises one or more of the following steps: heating a vessel comprising a precursor and at least one impurity to a temperature sufficient to vaporize at least a portion of the at least one impurity; measuring a vapor pressure within the vessel over time to obtain a plurality of measured vapor pressures and comparing the plurality of measured vapor pressures to a set point vapor pressure; and when at least one of the plurality of measured vapor pressures is greater than the set point vapor pressure, removing a vapor comprising the at least one impurity from the vessel. In some embodiments, when the vapor comprising the at least one impurity is removed from the vessel, at least 90% of the at least one impurity is removed from the vessel.

Some embodiments relate to a method. In some embodiments, the method comprises obtaining a vessel assembly. In some embodiments, the vessel assembly comprises a vessel defining an interior volume. In some embodiments, the vessel assembly comprises at least one tray located in the interior volume of the vessel. In some embodiments, the vessel assembly comprises a precursor located on the at least one tray. In some embodiments, the vessel assembly comprises at least one impurity located in the interior volume of the vessel. In some embodiments, the method comprises heating at least the vessel to a first temperature sufficient to vaporize at least a portion of the at least one impurity and to obtain a first vapor comprising the at least one impurity. In some embodiments, the method comprises removing the first vapor from the vessel such that, when the precursor is vaporized at a purification temperature to obtain a vaporized precursor, a vapor pressure of the vaporized precursor is within 10% of a theoretical vapor pressure of the precursor at the purification temperature.

Some embodiments relate to a method. In some embodiments, the method comprises obtaining a vessel assembly. In some embodiments, the vessel assembly comprises a vessel defining an interior volume. In some embodiments, the vessel assembly comprises at least one tray located in the interior volume of the vessel. In some embodiments, the vessel assembly comprises an aluminum precursor located on the at least one tray. In some embodiments, the vessel assembly comprises at least one impurity located in the interior volume of the vessel. In some embodiments, the at least one impurity comprises a water. In some embodiments, the water is located in at least one of the at least one tray, the aluminum precursor, or any combination thereof. In some embodiments, the method comprises heating at least the vessel to a first temperature sufficient to vaporize at least a portion of the at least one impurity to obtain a first vapor comprising the at least one impurity. In some embodiments, the method comprises removing the first vapor from the vessel such that, when the aluminum precursor is vaporized at a purification temperature to obtain a vaporized precursor, a vapor pressure of the vaporized precursor is within 10% of a theoretical vapor pressure of the precursor at the purification temperature.

Some embodiments relate to a method. In some embodiments, the method comprises obtaining a vessel assembly. In some embodiments, the vessel assembly comprises a vessel defining an interior volume. In some embodiments, the vessel assembly comprises at least one tray located in the interior volume of the vessel. In some embodiments, the vessel assembly comprises a molybdenum precursor located on the at least one tray. In some embodiments, the vessel assembly comprises at least one impurity located in the interior volume of the vessel. In some embodiments, the at least one impurity comprises a water. In some embodiments, the water is located in at least one of the at least one tray, the molybdenum precursor, or any combination thereof. In some embodiments, the method comprises heating at least the vessel to a first temperature sufficient to vaporize at least a portion of the at least one impurity to obtain a first vapor comprising the at least one impurity. In some embodiments, the method comprises removing the first vapor from the vessel such that, when the molybdenum precursor is vaporized at a purification temperature to obtain a vaporized precursor, a vapor pressure of the vaporized precursor is within 10% of a theoretical vapor pressure of the precursor at the purification temperature.

Some embodiments relate to a vessel assembly. In some embodiments, the vessel assembly comprises a vessel body defining an interior volume. In some embodiments, the vessel assembly comprises a tray located in the interior volume of the vessel body. In some embodiments, the vessel assembly comprises a precursor located on the tray. In some embodiments, the precursor comprises at one of an aluminum precursor, a molybdenum precursor, or any combination thereof. In some embodiments, when the precursor is vaporized at the purification temperature to obtain a vaporized precursor, a vapor pressure of the vaporized precursor is within 10% of a theoretical vapor pressure of the precursor at the purification temperature.

### BRIEF DESCRIPTION OF FIGURES

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for removing at least one impurity, according to some embodiments.

FIG. 2 is a schematic diagram of a system for removing at least one impurity, according to some embodiments.

FIG. 3 is a flowchart of a method for removing at least one impurity, according to some embodiments.

FIG. 4 is a schematic diagram of a vessel assembly, according to some embodiments.

FIG. 5 is a Fourier-transform infrared spectrum illustrating a presence of impurities in a vessel, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Precursors useful in fabrication of microelectronics, such as, for example and without limitation, semiconductors, contain impurities. The presence of these impurities in precursor vapors is undesirable because, among other things, the impurities are deposited on the substrate and are thus should be removed. The removal of these impurities remains an ongoing challenge due to the difficulties in minimizing or eliminating exposure to moisture and other conditions that result in the formation of impurities, as well as volatilization of impurities and/or contaminants, among other things. Conventional processes for removing these impurities and/or contaminants have various disadvantages, such as, for example and without limitation, prolonged startup processes, issues controlling impurity levels, and the like.

The methods and systems disclosed herein overcome the disadvantages of the conventional processes and systems. In some embodiments, for example, the methods disclosed herein can be employed to reduce the duration of startup processes and/or preconditioning steps, which are employed prior to use of the precursors in downstream processes. In some embodiments, the methods and systems disclosed herein provide high purity precursors suitable for use in the fabrication of microelectronics, such as, for example and without limitation, the fabrication of semiconductors. In some embodiments, the methods and systems disclosed herein overcome challenges relating to exposure to moisture, which may react to form impurities and/or contaminants. In some embodiments, the methods and systems disclosed herein remove volatile impurities. In some embodiments, the methods and systems disclosed herein provide mechanism for driving undesirable reactions to completion such that impurities can be formed and removed, while minimizing opportunities for impurities to reform (e.g., via reversible reactions and/or change in conditions driving equilibrium).

Some embodiments relate to a method for removing at least one impurity. Various embodiments of the method for removing the at least one impurity are provided herein. It will be appreciated that any combination of steps, in any order, may be performed in the method for removing the at least one impurity, without departing from the scope of this disclosure. Accordingly, that various methods and the steps of those methods are depicted in different figures shall not be limiting, as any combination of steps in any of the figures disclosed herein, in any combination, may be performed, without departing from the scope of this disclosure. Unless provided otherwise herein, the terms impurity and contaminant may be used interchangeably, without departing from the scope of this disclosure.

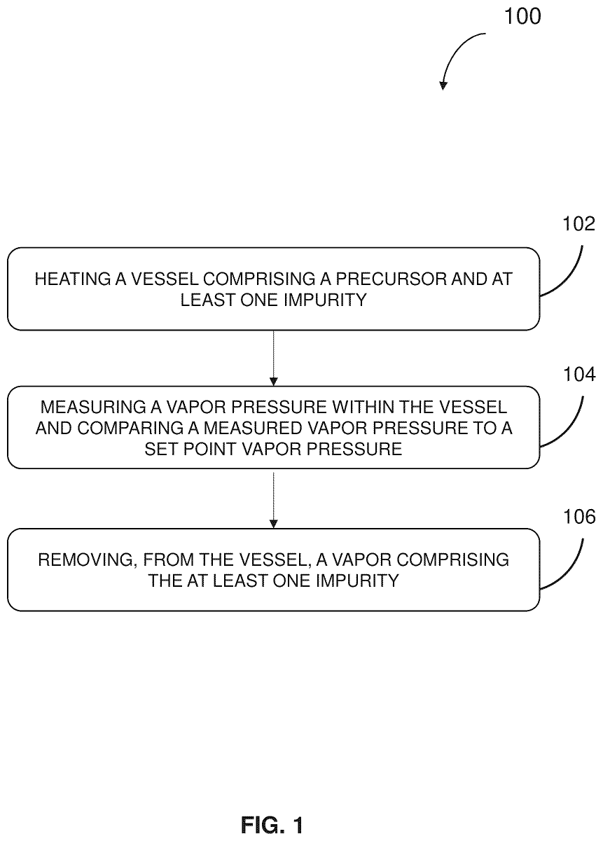

FIG. 1 is a flowchart of a method 100 for removing at least one impurity, according to some embodiments. As shown in FIG. 1, the method 100 for removing at least one impurity comprises one or more of the following steps: heating 102 a vessel comprising a precursor and at least one impurity, sufficient to vaporize at least a portion of the at least one impurity; measuring 104 a vapor pressure within the vessel to obtain a measured vapor pressure and comparing the measured vapor pressure to a set point vapor pressure; and removing 106, from the vessel, at least a portion of a vapor comprising the at least one impurity.

At step 102, in some embodiments, the method 100 comprises heating a vessel comprising a precursor and at least one impurity, sufficient to vaporize at least a portion of the at least one impurity.

In some embodiments, the vessel comprises at least one of a precursor, at least one impurity, or any combination thereof. In some embodiments, the vessel comprises at least one of a solid precursor, a liquid precursor, a gas/vapor precursor, or any combination thereof. In some embodiments, the vessel comprises at least one impurity, which may be present in at least one of a solid phase, a liquid phase, a gas/vapor phase, or any combination thereof. In some embodiments, the at least one impurity comprises at least one of a volatile impurity, a non-volatile impurity, or any combination thereof. In some embodiments, the at least one impurity comprises a non-reactive impurity, wherein the non-reactive impurity is an impurity which is not a reaction product with water (e.g., moisture). In some embodiments, the at least one impurity is a reaction product of water. In some embodiments, the at least one impurity is a reaction product of water and the precursor (e.g., results from exposure of the precursor to moisture or water vapor). In some embodiments, the at least one impurity comprises a hydrolyzed species. In some embodiments, the at least one impurity comprises an oxide. In some embodiments, the at least one impurity comprises at least one of HCl, an oxide, a hydrolyzed species (e.g., an aluminum chlorohydrate), molydioxydichloride, or any combination thereof. In some embodiments, the at least one impurity comprises a hydrated species. In some embodiments, the at least one impurity comprises a substance other than the precursor.

In some embodiments, the at least one impurity comprises at least one of molybdenum tetrachloride (MoCl₄), molybdenum oxytetrachloride (MoOCl₄), molybdenum dioxydichloride (MoO₂Cl₂), molybdenum dioxydichloride (MoO₂Cl₂(H₂O)), molybdenum trioxide (MoO₃), dichloromethane, phosgene, 1,1-dichloroethane, chloroform, 1,2-dichloroethane, carbon tetrachloride, tetrachloroethylene, trichlorethylene, 1,3-,dichloropropane, 1,2,3-trichloropropane, 1,2-dichloropropane, 1,1,2-trichloroethane, 1,1,2-trichloropropane, 1,2,2-trichloropropane, 1,1,2,3-tetrachloropropane, 1,2,2,3-tetrachloropropane, 1,1,2,2,-tetrachloroethane, 2,2-dichloropropanoyl chloride, 1,3-dichloro-1-propene, 3,3,3-trichloro-1-propene, 1,2,3-trichloro-1-propene, 1,3-dichloro-2-methylenepropane, 1,4-dichlorobutane, 1,3-dichloro-2-butene, 1,1,3,3-tetrachloro-2-methylpropane, 1,1,2,3,3-pentachloropropane, 1,3-dichlorocyclopentane, 1,1,2,2,3,3-hexachloropropane, 1,2,3,4,5,5-hexanechloro-1,3-cyclopentadiene, trichlorocyclopentene, tetrachlorocyclopentene, pentachloronorbornene, or any combination thereof.

In some embodiments, the precursor comprises at least one of aluminum chloride (e.g., AlCl₃), molybdenum chloride (e.g., MoCl₅), tungsten chloride (e.g., WCl₅, WCl₆), or any combination thereof. In some embodiments, the precursor comprises at least one of dimethyl hydrazine, trimethyl aluminum (TMA), hafnium chloride (HfCl₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr(t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(diethylamino)tantalum (TBTDET), pentakis(dimethylamino)tantalum (PDMAT), pentakis(ethylmethylamino)tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof. In some embodiments, the precursor does not comprise molybdenum pentachloride (MoCl₅). In some embodiment, the precursor does not comprise a tungsten precursor.

In some embodiments, the precursor comprises at least one of decaborane, hafnium tetrachloride, zirconium tetrachloride, indium trichloride, metalorganic β-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbonyl, or any combination thereof.

In some embodiments, the precursor comprises at least one of elemental metal, metal halides, metalorganic complexes, or any combination thereof. For example, in some embodiments, the precursor comprises at least one of elemental boron, copper, phosphorus, decaborane, gallium halides, indium halides, antimony halides, arsenic halides, gallium halides, aluminum iodide, titanium iodide, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the precursor comprises at least one of any type of source material that can be liquefied either by heating or solubilization in a solvent including, for example and without limitation, at least one of decaborane, (B₁₀H₁₄), pentaborane (B₅H₉), octadecaborane (B₁₈H₂₂), boric acid (H₃BO₃), SbCl₃, SbCl₅, or any combination thereof. In some embodiments, the precursor comprises at least one of at least one of AsCl₃, AsBr₃, AsF₃, AsF₅, AsH₃, As₄O₆, As₂Se₃m As₂S₂, As₂S₃, As₂S₅, As₂Te₃, B₄H₁₁, B₄H₁₀, B₃H₆N₃, BBr₃, BCl₃, BF₃, BF₃·O(C₂H₅)₂, BF₃·HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCl₃, SiCl₄, SiH₃Cl, NH₃, NH₃, Ar, Br₂, HBr, BrF₅, CO₂, CO, COCl₂, COF₂, Cl₂, ClF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCl₅, PF₃, PFS, SbH₃, SO₂, SF₆, SF₄, Si(OC₂H₅)₄, C₄H₁₆Si₄O₄, Si(CH₃)₄, SiH(CH₃)₃, TiCl₄, Xe, SiF₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof.

In some embodiments, the solvent(s) is an organic solvent, an inorganic solvent, or any combination hereof. In some embodiments, the solvent(s) contains forms of arsenic, phosphorus, antimony, germanium, indium, tin, selenium, tellurium, fluorine, carbon, boron, aluminum, bromine, carbon, chlorine, nitrogen, silicon, tungsten, tantalum, ruthenium, selenium, nickel, sulfur, or any combination thereof. It will be appreciated that other precursors may be used herein without departing from this disclosure.

The precursor may comprise 0.1% to 15% by weight of the at least one impurity based on a total weight of the precursor, or any range or subrange between 0.1% to 15%. In some embodiments, the precursor comprises 0.1% to 14%, 0.1% to 13%, 0.1% to 12%, 0.1% to 11%, 0.1% to 10%, 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, or 0.1% to 0.5% by weight of the at least one impurity based on the total weight of the precursor. In some embodiments, the precursor comprises 0.5% to 15%, 1% to 15%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, or 14% to 15% by weight of the at least one impurity based on the total weight of the precursor.

The vessel may be configured to control temperature. The temperature of the vessel may be controlled in any suitable manner. In some embodiments, a thermal jacket for heating and/or cooling is employed around the vessel. In some embodiments, a ribbon heater is wound around the vessel. In some embodiments, a block heater having a shape covering at least a major portion of the external surface of the vessel is employed to heat the vessel. In some embodiments, a resistive heater is employed to heat the vessel. In some embodiments, a lamp heater is employed to heat the vessel. In some embodiments, a heat transfer fluid at elevated temperature may be contacted with the exterior surface of the vessel, to effect heating and/or cooling thereof. In some embodiments, the heating is conducted by infrared or other radiant energy being impinged on the vessel. In some embodiments, the vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The vessel may be heated to a temperature and/or for a duration sufficient to vaporize the at least one impurity. In some embodiments, the vessel is heated to a temperature and/or for a duration sufficient for a reaction between the precursor and moisture or other substance to proceed to completion. In some embodiments, by proceeding to completion, the reaction is less likely to proceed in a reverse direction. In some embodiments, by proceeding to completion, all undesirable byproducts are formed and thus, being formed, can be removed from vessel to improve the purity level of the precursor. In some embodiments, the reaction does not proceed to completion.

The vessel may be heated to a temperature of 50° C. to 300° C., or any range or subrange between 50° C. and 300° C. In some embodiments, the vessel is heated to a temperature of 50° C. to 290° C., 50° C. to 280° C., 50° C. to 270° C., 50° C. to 260° C., 50° C. to 250° C., 50° C. to 240° C., 50° C. to 230° C., 50° C. to 220° C., 50° C. to 210° C., 50° C. to 200° C., 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., or 50° C. to 60° C. In some embodiments, the vessel is heated to a temperature of 60° C. to 300° C., 70° C. to 300° C., 80° C. to 300° C., 90° C. to 300° C., 100° C. to 300° C., 100° C. to 250° C., 100° C. to 200° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

The vessel may be maintained at the heated temperature for a duration of 30 seconds to 7 days, or any range or subrange between 30 seconds and 7 days. In some embodiments, the vessel may be heated for a duration of 1 minute to 7 days, 1 hour to 7 days, 4 hours to 7 days, 12 hours to 7 days, 24 hours to 7 days, 1 day to 7 days, 2 days to 7 days, 3 days to 7 days, 4 days to 7 days, 5 days to 7 days, 6 days to 7 days, 30 seconds to 6 days, 30 seconds to 5 days, 30 seconds to 4 days, 30 seconds to 3 days, 30 seconds to 2 days, 30 seconds to 1 day, 30 seconds to 12 hours, 30 seconds to 6 hours, 30 seconds to 4 hours, 4 hours to 48 hours, 4 hours to 24 hours, 8 hours to 48 hours, 8 hours to 24 hours, 12 hours to 24 hours, 12 hours to 48 hours, 24 hours to 48 hours, or 36 hours to 48 hours.

The vessel may be configured to control pressure. The pressure of the vessel may be controlled in any suitable manner. In some embodiments, a gas inlet line is fluidly coupled to the vessel. The gas inlet line may be configured to supply a pressurizing gas from a pressurizing gas source to the vessel. Control of the pressurizing gas into the vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the vessel. The vacuum line may be configured to apply a vacuum to the vessel. In some embodiments, the pumping speed is controlled by butterfly valves. It will be appreciated that other mechanisms for controlling the pressure of the vessel may be employed herein without departing from the scope of this disclosure. In some embodiments, the method comprises depressurizing the vessel. In some embodiments, the method comprises pressurizing the vessel. In some embodiments, the step of depressurizing and/or the step of pressurizing is performed during the step of heating.

The vessel may be pressurized (or depressurized) to a pressure of 0.001 Torr to 100 Torr, or any range or subrange therebetween. In some embodiments, the pressure is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 4 Torr, 0.01 Torr to 3 Torr, 0.01 Torr to 2 Torr, 0.01 Torr to 1 Torr, 0.01 Torr to 0.1 Torr, 0.001 Torr to 10 Torr, 0.001 Torr to 5 Torr, 0.001 Torr to 4 Torr, 0.001 Torr to 3 Torr, 0.001 Torr to 2 Torr, 0.001 Torr to 1 Torr, 0.001 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr.

At step 104, in some embodiments, the method 100 comprises measuring a vapor pressure within the vessel to obtain a measured vapor pressure and comparing the measured vapor pressure to a set point vapor pressure.

In some embodiments, the vapor pressure within the vessel is measured one or more times. In some embodiments, the vapor pressure within the vessel is measured over time. In some embodiments, the vapor pressure within the vessel is monitored over time. In some embodiments, the vapor pressure within the vessel is measured in real time. In some embodiments, the vapor pressure within the vessel is measured using a pressure sensor. In some embodiments, the vapor pressure within the vessel is measured using a pressure probe. In some embodiments, the vapor pressure within the vessel, once measured, is communicated to a controller. In some embodiments, the vapor pressure within the vessel, once measured, is communicated to a processor. In some embodiments, the processor and/or the controller receives a signal from the sensor and/or probe and converts the signal to the measured vapor pressure. In some embodiments, the vapor pressure, once measured, is stored in memory. In some embodiments, each measured vapor pressure is compared to the set point vapor pressure.

In some embodiments, the set point vapor pressure is a vapor pressure value. In some embodiments, the set point vapor pressure is a vapor pressure range. In some embodiments, the set point vapor pressure is a vapor pressure at least greater than a vapor pressure of the precursor. In some embodiments, the set point vapor pressure is a vapor pressure at least equal to a vapor pressure of the precursor. In some embodiments, the set point vapor pressure is a vapor pressure range, wherein a lower bound of the vapor pressure range is a pressure equal to a vapor pressure of the precursor. In some embodiments, the set point vapor pressure is a vapor pressure range, wherein a lower bound of the vapor pressure range is a pressure greater than a vapor pressure of the precursor. In some embodiments, the vapor pressure of the precursor refers to a vapor pressure of a pure form of the precursor, at conditions, which may be reported in literature or a measured value. The vapor pressure of the precursor may be useful as the set point vapor pressure because vapor pressures above the set point vapor pressure may be indicative of the presence of vapor and/or gas species other than the vaporized precursor.

At step 106, in some embodiments, the method 100 comprises removing 106, from the vessel, at least a portion of a vapor comprising the at least one impurity.

In some embodiments, at least a portion of the vapor comprising the at least one impurity is removed from the vessel so as to separate at least a portion of the impurity from the precursor. In some embodiments, at least a portion of the vapor comprising the at least one impurity is removed through an outlet of the vessel. In some embodiments, at least a portion of the vapor comprising the at least one impurity is removed via an outlet that is fluidly coupled to a gas discharge line. In some embodiments, at least a portion of the vapor comprising the at least one impurity is removed via an outlet that is fluidly coupled to a vacuum line (e.g., removing under vacuum). In some embodiments, at least a portion of the vapor comprising the at least one impurity is removed by opening a valve. In some embodiments, removing at least a portion of the vapor comprising the impurity from the vessel comprises removing a vapor phase in the headspace of the vessel. In some embodiments, removing at least a portion of the vapor comprising the impurity form the vessel comprises pumping the at least a portion of the vapor from the vessel. In some embodiments, the step of removing and the step of heating are performed at the same time.

In some embodiments, at least a portion of the vapor comprising the at least one impurity is removed from the vessel when the measured vapor pressure is above or within the set point vapor pressure. In some embodiments, at least a portion of the vapor comprising the at least one impurity is removed from the vessel when the measured vapor pressure is greater than 1 times the set point vapor pressure. In some embodiments, at least a portion of the vapor comprising the at least one impurity is removed from the vessel when the measured vapor pressure is greater than 1.1 times, 1.2 times, 1.3 times, 1.4 times, or 1.5 times the set point vapor pressure. In some embodiments, when the measured vapor pressure is greater than the set point vapor pressure, before removing at least a portion of the vapor comprising the at least one impurity, the vessel may be maintained at the heated temperature for an additional duration of 30 seconds to 7 days, or any range or subrange between 30 seconds and 7 days. In some embodiments, the vessel may be heated for an additional duration of 1 minute to 7 days, 1 hour to 7 days, 4 hours to 7 days, 12 hours to 7 days, 24 hours to 7 days, 1 day to 7 days, 2 days to 7 days, 3 days to 7 days, 4 days to 7 days, 5 days to 7 days, 6 days to 7 days, 30 seconds to 6 days, 30 seconds to 5 days, 30 seconds to 4 days, 30 seconds to 3 days, 30 seconds to 2 days, 30 seconds to 1 day, 30 seconds to 12 hours, 30 seconds to 6 hours, 30 seconds to 4 hours, 4 hours to 48 hours, 4 hours to 24 hours, 8 hours to 48 hours, 8 hours to 24 hours, 12 hours to 24 hours, 12 hours to 48 hours, 24 hours to 48 hours, or 36 hours to 48 hours.

In some embodiments, prior to removing at least a portion of the vapor comprising the at least one impurity, the vessel is allowed to cool to a temperature, wherein the temperature to which the vessel is allowed to cool is less than a temperature to which the vessel was heated. In some embodiments, prior to removing at least a portion of the vapor comprising the at least one impurity, the vessel is cooled to a temperature sufficient to condense at least a portion of a vapor comprising the precursor. In some embodiments, prior to removing at least a portion of the vapor comprising the at least one impurity, the vessel is cooled to ambient temperature. In some embodiments, after the vessel is cooled and prior to removing at least a portion of the vapor comprising the at least one impurity, the vessel is held at the cooled temperature for a duration of 30 seconds to 7 days, or any range or subrange between 30 seconds and 7 days. In some embodiments, the vessel may be heated for an additional duration of 1 minute to 7 days, 1 hour to 7 days, 4 hours to 7 days, 12 hours to 7 days, 24 hours to 7 days, 1 day to 7 days, 2 days to 7 days, 3 days to 7 days, 4 days to 7 days, 5 days to 7 days, 6 days to 7 days, 30 seconds to 6 days, 30 seconds to 5 days, 30 seconds to 4 days, 30 seconds to 3 days, 30 seconds to 2 days, 30 seconds to 1 day, 30 seconds to 12 hours, 30 seconds to 6 hours, 30 seconds to 4 hours, 4 hours to 48 hours, 4 hours to 24 hours, 8 hours to 48 hours, 8 hours to 24 hours, 12 hours to 24 hours, 12 hours to 48 hours, 24 hours to 48 hours, or 36 hours to 48 hours.

In some embodiments, at least a portion of the vapor comprising the at least one impurity is removed while the vessel is under heating. In some embodiments, at least a portion of the vapor comprising the at least one impurity is removed in real time, in response to a signal from a controller. For example, in some embodiments, whenever a measured vapor pressure, which is continuously monitored and/or measured, is above the set point vapor pressure, a controller and/or processor sends a signal to cause at least a portion of the vapor comprising the at least one vapor to be removed from the vessel.

The removing may be sufficient to remove all or at least a portion of the at least one impurity from the vessel. In some embodiments, the removing removes a sufficient amount of the at least one impurity such that the duration of the startup processing and/or preconditioning is less than the startup duration and/or preconditioning duration of a vessel not subjected to the methods disclosed herein. In some embodiments, the removing is sufficient to eliminate any startup processing and/or preconditioning steps. In some embodiments, the removing is sufficient such that, when the precursor is vaporized after performing the methods disclosed herein and the vapor pressure is measured, the measured vapor pressure is within 20%, within 15%, within 10%, within 9%, within 8%, within 7%, within 6%, within 5%, within 4%, within 3%, within 2%, or within 1% of the vapor pressure of the precursor (e.g., without the impurity). In some embodiments, when the precursor is vaporized after performing the method disclosed herein, the precursor has a purity of at least 80%, at least 85%, at least 90%, at least 95%, at least 96%, at least 97%, at least 98%, at least 99%, at least 99.9%, at least 99.99%, at least 99.999%, or at least 99.9999%, up to 100%.

The method may comprise at least one thermal cycle. In some embodiments, a thermal cycle comprises heating the vessel to a first temperature sufficient to vaporize at least a portion of the at least one impurity, cooling the vessel to a second temperature; and removing at least a portion of a vapor comprising the at least one impurity. In some embodiments, the method comprises 1 to 100 thermal cycles, or more. For example in some embodiments, the method comprises 1 to 90, 1 to 80, 1 to 70, 1 to 60, 1 to 50, 1 to 40, 1 to 30, 1 to 20, 1 to 10, 1 to 9, 1 to 8, 1 to 7, 1 to 6, 1 to 5, 1 to 4, 1 to 3, 1 to 2, 10 to 100, 20 to 100, 30 to 100, 40 to 100, 50 to 100, 60 to 100, 70 to 100, 80 to 100, or 90 to 100 thermal cycles. In some embodiments, the at least one thermal cycle comprises measuring the vapor pressure and comparing the measured vapor pressure to the set point vapor pressure. In some embodiments, the at least one thermal cycle comprises communicating one or more signals as disclosed herein.

In some embodiments, when the method is performed in real-time, the vessel may be heated to a temperature sufficient to vaporize at least a portion of the at least one impurity, and removing (e.g., without cooling) a vapor comprising the at least one impurity. In some embodiments, the vapor comprising the at least one impurity is removed in response to a signal. The signal may be communicated whenever the measured vapor pressure, which is monitored and/or measured continuously in real time, is at or above the set point vapor pressure. In some embodiments, the method is performed until a target vapor pressure is maintained or stabilized, thereby indicating the removal of at least a portion of the at least one impurity. In some embodiments, the target vapor pressure is the set point vapor pressure. Once maintained, the vessel is cooled and optionally filled with an inert gas.

In some embodiments, the method may further comprise, upon removing at least a portion of the vapor comprising the at least one impurity, filling the vessel with an inert gas. In some embodiments, the inert gas comprises at least one of hydrogen, argon, helium, nitrogen, or any combination thereof. In some embodiments, the method may further comprise, prior to heating the vessel, filling the vessel with any one or more of the precursors disclosed herein. In some embodiments, the method may further comprise, after removing at least a portion of the vapor comprising the at least one impurity, vaporizing the precursor and flowing the precursor to a semiconductor processing tool. In some embodiments, after removing at least a portion of the vapor comprising the at least one impurity, the vessel comprises less of the at least one impurity than a control vessel which is not subjected to the at least one thermal cycle.

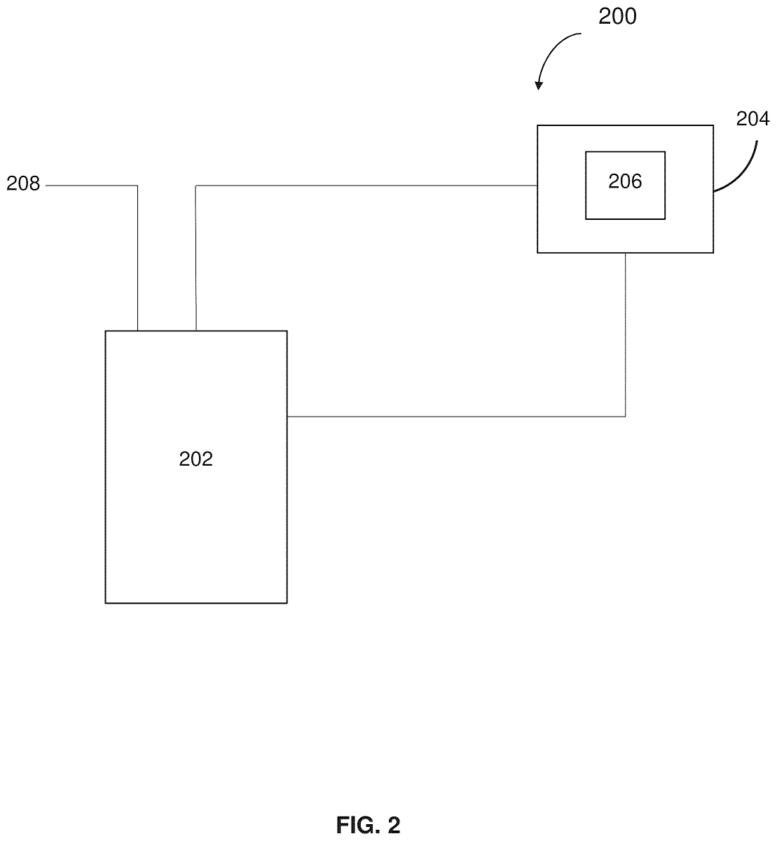

FIG. 2 is a schematic diagram of a system 200 for removing at least one impurity, according to some embodiments. In some embodiments, the system 200 comprises a vessel 202 comprising a precursor and at least one impurity. In some embodiments, the system 200 comprises at least one of a pressure sensor (not shown), a controller 204, a processor 206, a gas discharge line 208, a valve (not shown), or any combination thereof. In some embodiments, the pressure sensor is configured to measure a vapor pressure within the vessel 202. In some embodiments, the pressure sensor is configured to communicate a signal to at least one of a controller 204 and/or a processor 206. In some embodiments, the pressure sensor is configured to store a measured vapor pressure. In some embodiments, the processor 206 is configured to compare the measured vapor pressure to a set point vapor pressure. In some embodiments, the processor 206 is configured to send a signal to a controller 204 when the measured vapor pressure is at or above the set point vapor pressure. In some embodiments, the controller 204 is configured to actuate a valve or otherwise remove a vapor comprising the at least one impurity from the vessel 202. In some embodiments, the vapor comprising the at least one impurity is removed from the vessel 202 through an outlet of the vessel 202 and the gas discharge line 208. In some embodiments, the controller 204 and the processor 206 are the same.

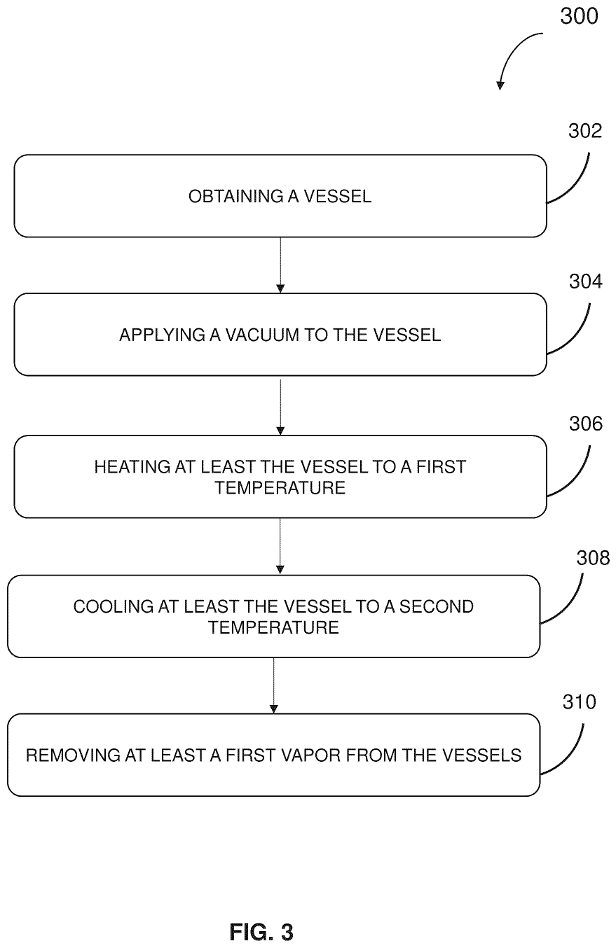

FIG. 3 is a flowchart of a method 300 for removing at least one impurity, according to some embodiments. As shown in FIG. 3, in some embodiments, the method 300 for removing at least one impurity comprises one or more of the following steps: obtaining 302 a vessel; applying 304 at least a vacuum to the vessel; heating 306 at least the vessel to a first temperature; cooling 308 at least the vessel to a second temperature; and removing 310 at least a first vapor from the vessel. It will be appreciated that any one or more of the steps may or may not be performed, without departing from the scope of this disclosure. It will further be appreciated that any one or more of the steps may be performed in any order. In some embodiments, the method 300 for removing at least one impurity is performed as a pretreatment step or as part of a startup process, etc. For example, in some embodiments, the method 300 for removing at least one impurity is performed prior to vaporizing a precursor for delivery to a semiconductor tool. For example, in some embodiments, although not shown, the method 300 further comprises heating the vessel to a temperature sufficient to vaporize at least a portion of the precursor and to obtain a vaporized precursor; and flowing the vaporized precursor to a semiconductor tool (e.g., a vapor deposition apparatus, etc.).

At step 302, in some embodiments, the method 300 for removing at least one impurity comprises obtaining a vessel.

It will be appreciated that any one or more of the vessels disclosed herein may be employed, without departing from the scope of this disclosure. In some embodiments, the vessel is part of a vessel assembly. The vessel may define an interior volume, and may have an inlet and an outlet. The vessel may contain one or more components located in the interior volume of the vessel. For example, in some embodiments, the vessel comprises at least one tray located in the interior volume of the vessel. The number of trays located in the interior volume of the vessel may be in a range of 1 tray to 100 trays, or any number of trays between 1 tray and 100 trays. In some embodiments, the at least one tray is loaded into the vessel on a structural support. In some embodiments, the at least one tray is wedged against an inner wall (or other inner surface) of the vessel. In some embodiments, the at least one tray is bonded, adhered, or otherwise mechanically fastened to the vessel.

The vessel may contain or may be configured to contain a precursor. It will be appreciated that any one or more of the precursors disclosed herein may be employed, without departing from the scope of this disclosure. For example, in some embodiments, the precursor comprises an aluminum precursor, such as, for example and without limitation, AlCl₃. In some embodiments, the precursor comprises a molybdenum precursor, such as, for example and without limitation, MoO₂Cl₂. In some embodiments, the precursor is located on the at least one tray. In some embodiments, the precursor is loaded onto the at least one tray. In some embodiments, the precursor is located on an inner surface of the vessel, wherein the inner surface of the vessel is a surface other than a surface of the at least one tray. In some embodiments, the precursor (e.g., located on each of the at least one tray) may be present in the vessel in an amount sufficient to be vaporized.

The at least one tray may be constructed of at least one of a carbon material, a metal material, a ceramic material, a polymeric material, or any combination thereof. In some embodiments, for example, the at least one tray comprises at least one metal, a metal alloy, a graphite (e.g., high density graphite), a pyrolytic carbon, or any combination thereof. In some embodiments, the at least one tray comprises a stainless steel. In some embodiments, the at least one tray comprises a graphite. In some embodiments, the at least one tray comprises a graphite, and a pyrolytic carbon coating located on the graphite.

At least one impurity may be located within the interior volume of the vessel. In some embodiments, the at least one impurity is present within the at least one tray. In some embodiments, the at least one impurity is present within the precursor. In some embodiments, the at least one impurity is present within an inner surface of the vessel. It will be appreciated that any one or more of the impurities disclosed herein may be present within the vessel, without departing from the scope of this disclosure. For example, in some embodiments, the at least one impurity comprises a hydrated compound, such as, for example and without limitation, a hydrated aluminum compound, a hydrated molybdenum compound, or any combination thereof, among others. In some embodiments, the at least one impurity comprises a water. In some embodiments, the water may be present in the form of moisture (i.e., water moisture). In some embodiments, the water may be present in the form of liquid water. In some embodiments, the water may be present in the form of water vapor. In some embodiments, the at least one impurity is present in a form such that, when the at least one impurity is vaporized (e.g., when the vessel is heated), the at least one impurity (or at least a portion thereof) reacts with the precursor to form an undesirable compound, such as, a contaminant.

It will be appreciated that, when the vessel is part of a vessel assembly, the vessel assembly may comprise additional components, without departing from the scope of this disclosure. Non-limiting examples of the additional components include, for example and without limitation, at least one of a mass flow meter, a volumetric flow meter, a pressure sensor, a temperature sensor, a valve, a valve assembly, a controller, a processor, any other component disclosed herein, or any combination thereof.

At step 304, in some embodiments, the method 300 for removing at least one impurity comprises applying at least a vacuum to the vessel.

The vessel may be configured to control pressure. In some embodiments, the applying comprises depressurizing the vessel. In some embodiments, the applying comprises pumping the vessel so as to reduce a pressure within the vessel. In some embodiments, the applying comprises pumping the vessel so as to reduce a pressure within the vessel to less than 0.8 times the set point vapor pressure. In some embodiments, the applying comprises pumping the vessel so as to reduce a pressure within the vessel to less than 0.7 times, 0.6 times, 0.5 times, 0.4 times, 0.3 times, 0.2 times, or 0.1 times the set point vapor pressure. In some embodiments, the applying comprises pumping the vessel for a set amount of time so as to reduce a pressure within the vessel. In some embodiments, the set amount of time is 5 seconds to 120 seconds, or any range or subrange between 5 seconds to 120 seconds. In some embodiments, the set amount of time is 5 seconds to 110 seconds, 5 seconds to 100 seconds, 5 seconds to 90 seconds, 5 seconds to 80 seconds, 5 seconds to 70 seconds, 5 seconds to 60 seconds, 5 seconds to 50 seconds, 5 seconds to 40 seconds, 5 seconds to 30 seconds, 5 seconds to 20 seconds, 5 seconds to 10 seconds, 10 seconds to 120 seconds, 20 seconds to 120 seconds, 30 seconds to 120 seconds, 40 seconds to 120 seconds, 50 seconds to 120 seconds, 60 seconds to 120 seconds, 70 seconds to 120 seconds, 80 seconds to 120 seconds, 90 seconds to 120 seconds, 100 seconds to 120 seconds, or 110 seconds to 120 seconds.

In some embodiments, the applying comprises depressurizing the vessel. In some embodiments, the applying comprises pumping the vessel so as to reduce a pressure within the vessel. In some embodiments, the applying comprises reducing a pressure within the vessel. In some embodiments, the applying comprises connecting a vacuum pump to the vessel. In some embodiments, the applying comprises operating a vacuum pump connected to the vessel. In some embodiments, the applying comprises reducing a pressure within the vessel to a baseline pressure. In some embodiments, the applying comprises connecting a vacuum line to the vessel. The vacuum line may be configured to apply a vacuum to the vessel. In some embodiments, the pumping speed may be controlled by butterfly valves. It will be appreciated that other mechanisms for controlling the pressure of the vessel may be employed herein without departing from the scope of this disclosure.

The baseline pressure may comprise a pressure of 1 mTorr to 1000 mTorr, or any range or subrange between 1 mTorr and 1000 mTorr. For example, in some embodiments, the baseline pressure is a pressure of 1 mTorr to 900 mTorr, 1 mTorr to 800 mTorr, 1 mTorr to 700 mTorr, 1 mTorr to 600 mTorr, 1 mTorr to 500 mTorr, 1 mTorr to 400 mTorr, 1 mTorr to 300 mTorr, 1 mTorr to 200 mTorr, 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 1 mTorr to 50 mTorr, 100 mTorr to 1000 mTorr, 200 mTorr to 1000 mTorr, 300 mTorr to 1000 mTorr, 400 mTorr to 1000 mTorr, 500 mTorr to 1000 mTorr, 600 mTorr to 1000 mTorr, 700 mTorr to 1000 mTorr, 800 mTorr to 1000 mTorr, or 900 mTorr to 1000 mTorr.

The vessel may be under vacuum or at a baseline or reduced pressure for a duration of 30 seconds to 7 days, or any range or subrange between 30 seconds and 7 days. In some embodiments, the vessel may be under vacuum for a duration of 1 minute to 7 days, 1 hour to 7 days, 12 hours to 7 days, 24 hours to 7 days, 1 day to 7 days, 2 days to 7 days, 3 days to 7 days, 4 days to 7 days, 5 days to 7 days, 6 days to 7 days, 30 seconds to 6 days, 30 seconds to 5 days, 30 seconds to 4 days, 30 seconds to 3 days, 30 seconds to 2 days, 30 seconds to 1 day, 30 seconds to 12 hours, 30 seconds to 6 hours, 30 seconds to 4 hours, 1 hour to 12 hours, 1 hour to 8 hours, 1 hour to 6 hours, 8 hours to 48 hours, 8 hours to 24 hours, 12 hours to 24 hours, 12 hours to 48 hours, 24 hours to 48 hours, or 36 hours to 48 hours.

At step 306, in some embodiments, the method 300 for removing at least one impurity comprises heating at least the vessel to a first temperature.

The vessel may be configured to control temperature. The temperature of the vessel may be controlled in any suitable manner. In some embodiments, a thermal jacket for heating and/or cooling is employed around the vessel. In some embodiments, a ribbon heater is wound around the vessel. In some embodiments, a block heater having a shape covering at least a major portion of the external surface of the vessel is employed to heat the vessel. In some embodiments, a resistive heater is employed to heat the vessel. In some embodiments, a lamp heater is employed to heat the vessel. In some embodiments, a heat transfer fluid at elevated temperature may be contacted with the exterior surface of the vessel, to effect heating and/or cooling thereof. In some embodiments, the heating is conducted by infrared or other radiant energy being impinged on the vessel. In some embodiments, the vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The vessel may be heated to a temperature and/or for a duration sufficient to vaporize at least a portion of the at least one impurity and to obtain a first vapor comprising the at least one impurity (e.g., an impurity vapor). In some embodiments, at least a portion of the precursor is vaporized such that, the first vapor comprises the precursor (e.g., a precursor vapor). In some embodiments, the vessel is heated to a temperature and/or for a duration sufficient to vaporize the at least one impurity, while minimizing an amount of the precursor being vaporized. In some embodiments, the amount of the precursor being vaporized is modulated by controlling the temperature and/or the pressure within the vessel, such that the at least one impurity is vaporized without vaporizing the precursor or at least minimizing the amount of the precursor that is vaporized. In some embodiments, the vessel is heated to a temperature and/or for a duration sufficient for a reaction between the precursor and moisture or other substance to proceed to completion. In some embodiments, by proceeding to completion, the reaction is less likely to proceed in a reverse direction. In some embodiments, by proceeding to completion, all undesirable byproducts are formed and thus, being formed, can be removed from vessel to improve the purity level of the precursor. In some embodiments, the reaction does not proceed to completion.

The vessel may be heated to a first temperature of 50° C. to 300° C., or any range or subrange between 50° C. and 300° C. In some embodiments, the vessel is heated to a first temperature of 50° C. to 290° C., 50° C. to 280° C., 50° C. to 270° C., 50° C. to 260° C., 50° C. to 250° C., 50° C. to 240° C., 50° C. to 230° C., 50° C. to 220° C., 50° C. to 210° C., 50° C. to 200° C., 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., or 50° C. to 60° C. In some embodiments, the vessel is heated to a first temperature of 60° C. to 300° C., 70° C. to 300° C., 80° C. to 300° C., 90° C. to 300° C., 100° C. to 300° C., 100° C. to 250° C., 100° C. to 200° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

The vessel may be heated for a duration of 30 seconds to 7 days, or any range or subrange between 30 seconds and 7 days. In some embodiments, the vessel may be heated for a duration of 1 minute to 7 days, 1 hour to 7 days, 12 hours to 7 days, 24 hours to 7 days, 1 day to 7 days, 2 days to 7 days, 3 days to 7 days, 4 days to 7 days, 5 days to 7 days, 6 days to 7 days, 30 seconds to 6 days, 30 seconds to 5 days, 30 seconds to 4 days, 30 seconds to 3 days, 30 seconds to 2 days, 30 seconds to 1 day, 30 seconds to 12 hours, 30 seconds to 6 hours, 30 seconds to 4 hours, 1 hour to 12 hours, 1 hour to 8 hours, 1 hour to 6 hours, 8 hours to 48 hours, 8 hours to 24 hours, 12 hours to 24 hours, 12 hours to 48 hours, 24 hours to 48 hours, or 36 hours to 48 hours.

At step 308, in some embodiments, the method 300 for removing at least one impurity comprises cooling at least the vessel to a second temperature.

The vessel may be cooled to a second temperature and for a duration sufficient to separate the at least one impurity from the precursor. In some embodiments, when the first vapor comprises the precursor, the cooling is sufficient to condense at least a portion of the precursor vapor to separate the precursor from the at least one impurity. In some embodiments, when the first vapor comprises the precursor, the cooling is sufficient to separate at least a portion of the precursor from the at least one impurity. In some embodiments, the second temperature is a temperature sufficient to condense the precursor vapor. In some embodiments, the second temperature is a temperature sufficient to condense the precursor vapor, without condensing the impurity vapor or at least minimizing an amount of the impurity vapor condensed.

The second temperature may be a temperature that is less than the first temperature. For example, in some embodiments, the vessel may be cooled to a second temperature of 0° C. to 150° C., or any range or subrange between 0° C. and 150° C. In some embodiments, the vessel is cooled to a temperature of 10° C. to 150° C., 20° C. to 150° C., 30° C. to 150° C., 40° C. to 150° C., 50° C. to 150° C., 60° C. to 150° C., 70° C. to 150° C., 80° C. to 150° C., 90° C. to 150° C., 100° C. to 150° C., 110° C. to 150° C., 120° C. to 150° C., 130° C. to 150° C., 140° C. to 150° C., 0° C. to 140° C., 0° C. to 130° C., 0° C. to 120° C., 0° C. to 110° C., 0° C. to 100° C., 0° C. to 90° C., 0° C. to 80° C., 0° C. to 70° C., 0° C. to 60° C., 0° C. to 50° C., 0° C. to 40° C., 0° C. to 30° C., 0° C. to 20° C., or 0° C. to 10° C.

At step 310, in some embodiments, the method 300 for removing at least one impurity comprises removing at least a first vapor from the vessel.

In some embodiments, at least a portion of the first vapor comprising the at least one impurity is removed from the vessel so as to separate at least a portion of the at least one impurity from the precursor. In some embodiments, at least a portion of the first vapor comprising the at least one impurity is removed through an outlet of the vessel. In some embodiments, at least a portion of the first vapor comprising the at least one impurity is removed via an outlet that is fluidly coupled to a gas discharge line. In some embodiments, at least a portion of the first vapor comprising the at least one impurity is removed via an outlet that is fluidly coupled to a vacuum line (e.g., removing under vacuum). In some embodiments, at least a portion of the first vapor comprising the at least one impurity is removed by opening a valve. In some embodiments, removing at least a portion of the first vapor comprising the impurity from the vessel comprises removing a vapor phase in the headspace of the vessel.

In some embodiments, at least a portion of the first vapor comprising the at least one impurity is removed from the vessel when the measured vapor pressure is above or within the set point vapor pressure. In some embodiments, prior to removing at least a portion of the first vapor comprising the at least one impurity, the vessel is allowed to cool to a temperature, wherein the temperature to which the vessel is allowed to cool is less than a temperature to which the vessel was heated. In some embodiments, prior to removing at least a portion of the first vapor comprising the at least one impurity, the vessel is cooled to a temperature sufficient to condense at least a portion of a first vapor comprising the precursor. In some embodiments, at least a portion of the first vapor comprising the at least one impurity is removed while the vessel is under heating. In some embodiments, at least a portion of the first vapor comprising the at least one impurity is removed in real time, in response to a signal from a controller. For example, in some embodiments, whenever a measured vapor pressure, which is continuously monitored and/or measured, is above the set point vapor pressure, a controller and/or processor sends a signal to cause at least a portion of the vapor comprising the at least one vapor to be removed from the vessel.

The first vapor may be removed from the vessel such that, when the precursor is vaporized (or subsequently vaporized) at a purification temperature to obtain a vaporized precursor, a vapor pressure of the vaporized precursor is within 20% of a theoretical vapor pressure of the precursor at the purification temperature. For example, in some embodiments, the first vapor is removed from the vessel such that, when the precursor is vaporized at a purification temperature to obtain a vaporized precursor, a vapor pressure of the vaporized precursor is within 20%, within 19%, within 18%, within 17%, within 16%, within 15%, within 14%, within 13%, within 12%, within 11%, within 10%, within 9%, within 8%, within 7%, within 6%, within 5%, within 4%, within 3%, within 2%, within 1%, or within 0.1% of a theoretical vapor pressure of the precursor at the purification temperature. In some embodiments, when the precursor is vaporized after performing the method disclosed herein, the precursor has a purity of at least 80%, at least 85%, at least 90%, at least 95%, at least 96%, at least 97%, at least 98%, at least 99%, at least 99.9%, at least 99.99%, at least 99.999%, or at least 99.9999%, up to 100%.

In some embodiments, the method 300 for removing at least one impurity does not comprise a step of removing the precursor from the at least one tray and reloading the precursor onto the at least one tray. In some embodiments, the method 300 for removing at least one impurity does not comprise a step of exposing an interior volume of the vessel assembly to an ambient conditions (e.g., at least one of ambient temperature, ambient pressure, or any combination thereof) or an ambient environment, which may introduce contaminants and/or impurities into the vessel. In some embodiments, the method 300 for removing at least one impurity does not comprise a step of flowing a second vapor comprising the precursor from the vessel to a semiconductor tool (e.g., when the method is not performed at a semiconductor fabrication facility, etc.).

In some embodiments, the method 300 comprises obtaining a vessel assembly. In some embodiments, the vessel assembly comprises a vessel defining an interior volume. In some embodiments, the vessel assembly comprises at least one tray located in the interior volume of the vessel. In some embodiments, the vessel assembly comprises an aluminum precursor located on the at least one tray. In some embodiments, the vessel assembly comprises at least one impurity located in the interior volume of the vessel, wherein the at least one impurity comprises a water. In some embodiments, the water is located in at least one of the at least one tray, the aluminum precursor, or any combination thereof. In some embodiments, the method 300 comprises heating at least the vessel to a first temperature sufficient to vaporize at least a portion of the at least one impurity to obtain a first vapor comprising the at least one impurity. In some embodiments, the method 300 comprises removing the first vapor from the vessel such that, when the aluminum precursor is vaporized at a purification temperature to obtain a vaporized precursor, a vapor pressure of the vaporized precursor is within 10% of a theoretical vapor pressure of the precursor at the purification temperature.

In some embodiments, the method 300 comprises obtaining a vessel assembly. In some embodiments, the vessel assembly comprises a vessel defining an interior volume. In some embodiments, the vessel assembly comprises at least one tray located in the interior volume of the vessel. In some embodiments, the vessel assembly comprises a molybdenum precursor located on the at least one tray. In some embodiments, the vessel assembly comprises at least one impurity located in the vessel. In some embodiments, the at least one impurity comprises a water. In some embodiments, the water is located in at least one of the at least one tray, the molybdenum precursor, or any combination thereof. In some embodiments, the method 300 comprises heating at least the vessel to a first temperature sufficient to vaporize at least a portion of the at least one impurity to obtain a first vapor comprising the at least one impurity. In some embodiments, the method 300 comprises removing the first vapor from the vessel such that, when the molybdenum precursor is vaporized at a purification temperature to obtain a vaporized precursor, a vapor pressure of the vaporized precursor is within 10% of a theoretical vapor pressure of the precursor at the purification temperature.

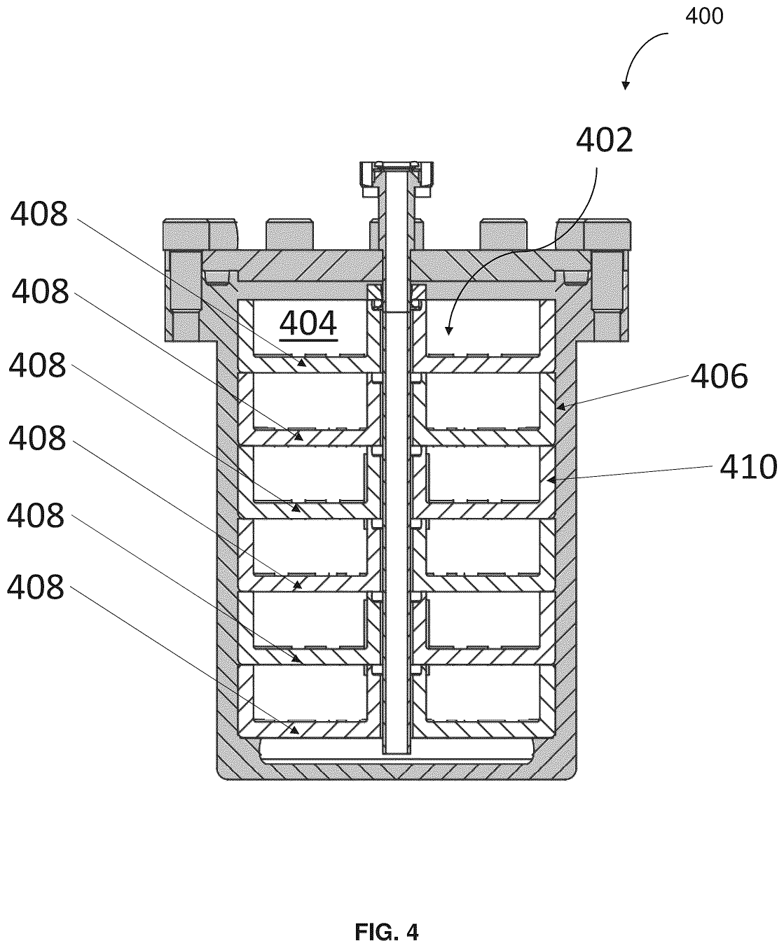

FIG. 4 is a schematic diagram of a cross-section of a vessel assembly, according to some embodiments. The vessel 400 contains a tray assembly 402 in an interior volume 404 of the vessel 400. The interior volume 404 has an inner wall surface 406. The tray assembly 402 comprises trays 408, each of which are configured to contain a vaporizable precursor. Each of the trays 408 of the tray assembly 402 comprises a portion 410 which is configured to be in contact (e.g., thermal contact, physical contact, etc.) with the inner wall surface 406 of the vessel 400. The surface-to-surface contact of the portion 410 with the inner wall surface 406 enhances heat transfer from the vessel 400 to each tray 408 and thus from each tray 408 to the vaporizable precursor on each tray 408. Various fluid flow paths are defined within the interior volume 404 of the vessel 400 such that a fluid is optionally allowed to flow through the vessel 400 upwards, downwards, or both. The vessel 400 is shown having a generally cylindrical inner chamber. However, it will be appreciated that the interior volume 404 of the ampoule may have other shapes without departing from the scope of this disclosure.

Any one or more of the embodiments disclosed herein shall be understood to be combinable without departing from the scope or spirit of the disclosure.

### Aspects

Various Aspects are described below. It is to be understood that any one or more of the features recited in the following Aspect(s) can be combined with any one or more other Aspect(s).
Aspect 1. A method comprising:
   at least one thermal cycle, wherein the at least one thermal cycle comprises:
      heating a vessel comprising a precursor and at least one impurity to a temperature for a duration sufficient to vaporize at least a portion of the at least one impurity;
      measuring a vapor pressure within the vessel to obtain a measured vapor pressure and comparing the measured vapor pressure to a set point vapor pressure; and
      when the measured vapor pressure is above or within the set point vapor pressure, removing, from the vessel, at least a portion of a vapor comprising the at least one impurity,
         wherein, when the vapor comprising the at least one impurity is removed from the vessel, at least 90% of the at least one impurity is removed from the vessel.
Aspect 2. The method according to Aspect 1, wherein the precursor is a solid precursor comprising the at least one impurity.
Aspect 3. The method according to any one of Aspects 1-2, wherein the vessel is heated to the temperature of 50° C. to 300° C.
Aspect 4. The method according to any one of Aspects 1-3, wherein the vessel is heated to the temperature of 100° C. to 250° C.
Aspect 5. The method according to any one of Aspects 1-4, wherein the vessel is heated to the temperature of 100° C. to 200° C.
Aspect 6. The method according to any one of Aspects 1-5, wherein the vessel is maintained at the temperature for a duration of 30 seconds to 7 days.
Aspect 7. The method according to any one of Aspects 1-6, wherein the vessel is maintained at the temperature for a duration of 4 hours to 48 hours.
Aspect 8. The method according to any one of Aspects 1-7, wherein the vessel is maintained at the temperature for a duration 4 hours to 24 hours.
Aspect 9. The method according to any one of Aspects 1-8, wherein the set point vapor pressure is a pressure greater than a vapor pressure of the precursor.
Aspect 10. The method according to any one of Aspects 1-9, wherein the set point vapor pressure is a vapor pressure range, wherein a lower bound of the vapor pressure range is a pressure greater than a vapor pressure of the precursor.
Aspect 11. The method according to any one of Aspects 1-10, further comprising cooling the vessel prior to removing at least a portion of the vapor comprising the at least one impurity from the vessel.
Aspect 12. The method according to any one of Aspects 1-11, wherein the method comprises one thermal cycle to 100 thermal cycles.
Aspect 13. The method according to any one of Aspects 1-12, wherein, when the vapor comprising the at least one impurity is removed from the vessel, at least 99% of the at least one impurity is removed from the vessel.
Aspect 14. A method comprising:
   heating a vessel comprising a precursor and at least one impurity to a temperature sufficient to vaporize at least a portion of the at least one impurity;
   measuring a vapor pressure within the vessel over time to obtain a plurality of measured vapor pressures and comparing the plurality of measured vapor pressures to a set point vapor pressure; and
   when at least one of the plurality of measured vapor pressures is greater than the set point vapor pressure, removing a vapor comprising the at least one impurity from the vessel,
      wherein, when the vapor comprising the at least one impurity is removed from the vessel, at least 90% of the at least one impurity is removed from the vessel.
Aspect 15. The method according to Aspect 14, wherein the vapor comprising the at least one impurity is removed from the vessel while the vessel is under heating.
Aspect 16. The method according to any one of Aspects 14-15, further comprising: cooling the vessel when at least 2 of the plurality of measured vapor pressures change less than 5% over time.
Aspect 17. The method according to Aspect 16, further comprising: filling the vessel with an inert gas after cooling the vessel.
Aspect 18. The method according to any one of Aspects 14-17, wherein the vessel is heated to the temperature of 50° C. to 300° C.
Aspect 19. The method according to any one of Aspects 14-18, wherein the vessel is maintained at the temperature for a duration of 30 seconds to 7 days.
Aspect 20. The method according to any one of Aspects 14-19, wherein, when the vapor comprising the at least one impurity is removed from the vessel, at least 99% of the at least one impurity is removed from the vessel.
Aspect 21. A method comprising:
   obtaining a vessel assembly,
      wherein the vessel assembly comprises:
         a vessel defining an interior volume;
         at least one tray located in the interior volume of the vessel;
         a precursor located on the at least one tray; and
         at least one impurity;
   heating at least the vessel to a first temperature sufficient to vaporize at least a portion of the at least one impurity and to obtain a first vapor comprising the at least one impurity; and
   removing the first vapor from the vessel such that,
      when the precursor is vaporized at a purification temperature to obtain a vaporized precursor, a vapor pressure of the vaporized precursor is within 10% of a theoretical vapor pressure of the precursor at the purification temperature.
Aspect 22. The method according to Aspect 21, wherein the precursor comprises an aluminum precursor.
Aspect 23. The method according to Aspect 22, wherein the aluminum precursor comprises AlCl₃.
Aspect 24. The method according to Aspect 22, wherein the at least one impurity comprises:
   a hydrated aluminum compound,
      wherein, prior to the heating, the hydrated aluminum compound is located in the aluminum precursor.
Aspect 25. The method according to Aspect 21, wherein the precursor comprises a molybdenum precursor.
Aspect 26. The method according to Aspect 25, wherein the molybdenum precursor comprises MoO₂Cl₂.
Aspect 27. The method according to Aspect 25, wherein the at least one impurity comprises:
   a water,
      wherein, prior to the heating, the water is located in the molybdenum precursor.
Aspect 28. The method according to any one of Aspects 21-27, wherein the at least one impurity comprises:
   a water,
      wherein, prior to the heating, the water is located in the at least one tray.
Aspect 29. The method according to any one of Aspects 21-28, wherein the at least one tray comprises at least one of a graphite, a pyrolytic carbon, or any combination thereof.
Aspect 30. The method according to any one of Aspects 21-29, wherein the at least one tray comprises a metal alloy.
Aspect 31. The method according to any one of Aspects 21-30, wherein the heating is conducted at a temperature of 50° C. to 300° C.
Aspect 32. The method according to any one of Aspects 21-31, wherein the heating is conducted at a pressure of 1 mTorr to 1000 mTorr.
Aspect 33. The method according to any one of Aspects 21-32, further comprising:
   after the heating and prior to the removing, cooling the vessel from the first temperature to a second temperature,
      wherein the second temperature is less than the first temperature.
Aspect 34. The method according to any one of Aspects 21-33, further comprising:
   prior to the heating, applying a vacuum sufficient to reduce a pressure within the vessel.
Aspect 35. The method according to any one of Aspects 21-34, wherein the method does not comprise a step of removing the precursor from the at least one tray and reloading the precursor onto the at least one tray.
Aspect 36. The method according to any one of Aspects 21-35, wherein the method does not comprise a step of exposing an interior volume of the vessel assembly to ambient.
Aspect 37. The method according to any one of Aspects 21-36, wherein the method does not comprise a step of flowing a second vapor comprising the precursor from the vessel to a semiconductor tool.
Aspect 38. A method comprising:
   obtaining a vessel assembly,
      wherein the vessel assembly comprises:
         a vessel defining an interior volume;
         at least one tray located in the interior volume of the vessel;
         an aluminum precursor located on the at least one tray; and
         at least one impurity comprises a water;
         wherein the water is located in at least one of the at least one tray, the aluminum precursor, or any combination thereof;
   heating at least the vessel to a first temperature sufficient to vaporize at least a portion of the at least one impurity to obtain a first vapor comprising the at least one impurity; and
   removing the first vapor from the vessel such that,
      when the aluminum precursor is vaporized at a purification temperature to obtain a vaporized precursor, a vapor pressure of the vaporized precursor is within 10% of a theoretical vapor pressure of the precursor at the purification temperature.
Aspect 39. A method comprising:
   obtaining a vessel assembly,
      wherein the vessel assembly comprises:
         a vessel defining an interior volume;
         at least one tray located in the interior volume of the vessel;
         a molybdenum precursor located on the at least one tray; and
         at least one impurity comprises a water;
         wherein the water is located in at least one of the at least one tray, the molybdenum precursor, or any combination thereof;
   heating at least the vessel to a first temperature sufficient to vaporize at least a portion of the at least one impurity to obtain a first vapor comprising the at least one impurity; and
   removing the first vapor from the vessel such that,
      when the molybdenum precursor is vaporized at a purification temperature to obtain a vaporized precursor, a vapor pressure of the vaporized precursor is within 10% of a theoretical vapor pressure of the precursor at the purification temperature.
Aspect 40. A vessel assembly comprising:
   a vessel body defining an interior volume;
   a tray located in the interior volume of the vessel body; and
   a precursor located on the tray;
      wherein the precursor comprises at one of an aluminum precursor, a molybdenum precursor, or any combination thereof,
      wherein, when the precursor is vaporized at the purification temperature to obtain a vaporized precursor, a vapor pressure of the vaporized precursor is within 10% of a theoretical vapor pressure of the precursor at the purification temperature.

### Example 1

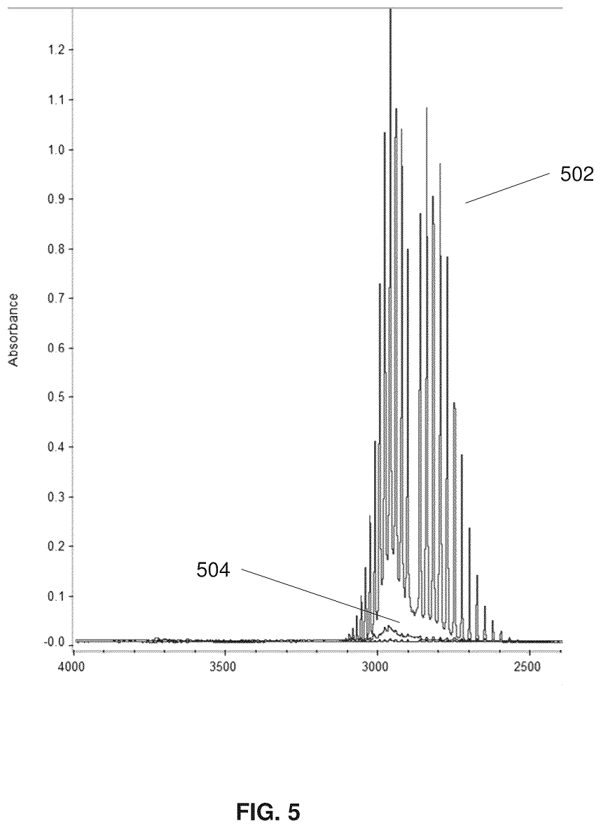

An ampoule was filled with an AlCl₃ precursor containing impurities and subjected to a first thermal cycle. That is, the ampoule was heated to 140° C. and held at that temperature for 8 hours. When a measured vapor pressure within the ampoule exceeded a theoretical vapor pressure for the precursor at the conditions of the measurement, the ampoule was allowed to cool and the amount of impurities present in the headspace was measured by FTIR and reported in FIG. 5 with reference numeral 502 (˜100-10 Torr). The headspace of the ampoule was then evacuated to remove a vapor comprising the impurities. The ampoule underwent a second thermal cycle. The amount of impurities present in the headspace was measured again by FTIR and reported in FIG. 5 with reference numeral 504 (<1 Torr).

### Example 2

An ampoule was filled with a MoO₂Cl₂ precursor containing impurities and subjected to a first thermal cycle. That is, the ampoule was heated to 140° C. and held at that temperature for 4 to 24 hours. When a measured pressure within the ampoule exceeded a theoretical vapor pressure for the precursor at the conditions of the measurement by greater than 1 to 1.5 times, the headspace of the ampoule was evacuated by pumping for 5 to 120 seconds to reduce the pressure within the ampoule and to remove a vapor comprising the impurities. The pressure in the ampoule was measured again after waiting 30 to 500 seconds. The procedure was repeated until the measured pressure within the ampoule was within 1 to 1.2 times the theoretical vapor pressure of the precursor at the conditions of the measurement. The ampoule was then allowed to cool and the amount of impurities present in the headspace was measured by FTIR and a pressure transducer. If the desired purity is not achieved, the ampoule undergoes further thermal cycles until a precursor having a purity of at least 99% is achieved.

### Example 3

An ampoule was filled with a MoCl₅ precursor containing impurities and subjected to a first thermal cycle. That is, the ampoule was heated to 140° C. and held at that temperature for 4 to 24 hours. When a measured pressure within the ampoule exceeded a theoretical vapor pressure for the precursor at the conditions of the measurement by greater than 1 to 1.5 times, the headspace of the ampoule was evacuated by pumping for 5 to 120 seconds to reduce the pressure within the ampoule and to remove a vapor comprising the impurities. The pressure in the ampoule was measured again after waiting 30 to 500 seconds. The procedure was repeated until the measured pressure within the ampoule was within 1 to 1.2 times the theoretical vapor pressure of the precursor at the conditions of the measurement. The ampoule was then allowed to cool and the amount of impurities present in the headspace was measured by FTIR and a pressure transducer. If the desired purity is not achieved, the ampoule undergoes further thermal cycles until a precursor having a purity of at least 99% is achieved.

### Example 4

An ampoule was filled with a WCl₅ precursor containing impurities and subjected to a first thermal cycle. That is, the ampoule was heated to 140° C. and held at that temperature for 4 to 24 hours. When a measured pressure within the ampoule exceeded a theoretical vapor pressure for the precursor at the conditions of the measurement by greater than 1 to 1.5 times, the headspace of the ampoule was evacuated by pumping for 5 to 120 seconds to reduce the pressure within the ampoule and to remove a vapor comprising the impurities. The pressure in the ampoule was measured again after waiting 30 to 500 seconds. The procedure was repeated until the measured pressure within the ampoule was within 1 to 1.2 times the theoretical vapor pressure of the precursor at the conditions of the measurement. The ampoule was then allowed to cool and the amount of impurities present in the headspace was measured by FTIR and a pressure transducer. If the desired purity is not achieved, the ampoule undergoes further thermal cycles until a precursor having a purity of at least 99% is achieved.

### Example 5

An ampoule was filled with an AlCl₃ precursor containing impurities and subjected to a first thermal cycle. That is, the ampoule was heated to 140° C. and held at that temperature for 4 to 24 hours. When a measured pressure within the ampoule exceeded a theoretical vapor pressure for the precursor at the conditions of the measurement by greater than 1 to 1.5 times, the ampoule was maintained at the heated temperature for another 4 to 24 hours. The pressure was measured again, and when the measured pressure did not reduce by at least 0.1 times the theoretical vapor pressure, the ampoule was allowed to cool and held at the cooled temperature for 4 to 24 hours. The headspace of the ampoule was then evacuated to remove a vapor comprising the impurities. The amount of impurities present in the headspace was measured by FTIR and a pressure transducer. If the desired purity is not achieved, the ampoule undergoes further thermal cycles until a precursor having a purity of at least 99% is achieved.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
at least one thermal cycle, wherein the at least one thermal cycle comprises:
heating a vessel comprising a precursor and at least one impurity to a temperature for a duration sufficient to vaporize at least a portion of the at least one impurity;
measuring a vapor pressure within the vessel to obtain a measured vapor pressure and comparing the measured vapor pressure to a set point vapor pressure; and
when the measured vapor pressure is above or within the set point vapor pressure, removing, from the vessel, at least a portion of a vapor comprising the at least one impurity,
wherein, when the vapor comprising the at least one impurity is removed from the vessel, at least 90% of the at least one impurity is removed from the vessel.

2. The method of claim 1, wherein the precursor is a solid precursor comprising the at least one impurity.

3. The method of claim 1, wherein the vessel is heated to the temperature of 50° C. to 300° C.

4. The method of claim 1, wherein the vessel is heated to the temperature of 100° C. to 250° C.

5. The method of claim 1, wherein the vessel is heated to the temperature of 100° C. to 200° C.

6. The method of claim 1, wherein the vessel is maintained at the temperature for a duration of 30 seconds to 7 days.

7. The method of claim 1, wherein the vessel is maintained at the temperature for a duration of 4 hours to 48 hours.

8. The method of claim 1, wherein the vessel is maintained at the temperature for a duration 4 hours to 24 hours.

9. The method of claim 1, wherein the set point vapor pressure is a pressure greater than a vapor pressure of the precursor.

10. The method of claim 1, wherein the set point vapor pressure is a vapor pressure range, wherein a lower bound of the vapor pressure range is a pressure greater than a vapor pressure of the precursor.

11. The method of claim 1, further comprising cooling the vessel prior to removing at least a portion of the vapor comprising the at least one impurity from the vessel.

12. The method of claim 1, wherein the method comprises one thermal cycle to 100 thermal cycles.

13. The method of claim 1, wherein, when the vapor comprising the at least one impurity is removed from the vessel, at least 99% of the at least one impurity is removed from the vessel.

14. A method comprising:
heating a vessel comprising a precursor and at least one impurity to a temperature sufficient to vaporize at least a portion of the at least one impurity;
measuring a vapor pressure within the vessel over time to obtain a plurality of measured vapor pressures and comparing the plurality of measured vapor pressures to a set point vapor pressure; and
when at least one of the plurality of measured vapor pressures is greater than the set point vapor pressure, removing a vapor comprising the at least one impurity from the vessel,
wherein, when the vapor comprising the at least one impurity is removed from the vessel, at least 90% of the at least one impurity is removed from the vessel.

15. The method of claim 14, wherein the vapor comprising the at least one impurity is removed from the vessel while the vessel is under heating.

16. The method of claim 14, further comprising: cooling the vessel when at least 2 of the plurality of measured vapor pressures change less than 5% over time.

17. The method of claim 16, further comprising: filling the vessel with an inert gas after cooling the vessel.

18. The method of claim 14, wherein the vessel is heated to the temperature of 50° C. to 300° C.

19. The method of claim 14, wherein the vessel is maintained at the temperature for a duration of 30 seconds to 7 days.

20. The method of claim 14, wherein, when the vapor comprising the at least one impurity is removed from the vessel, at least 99% of the at least one impurity is removed from the vessel.
